(19) United States
(12) Patent Application Publication
(10) Pub. No.: US 2003/0137031 A1
(43) Pub. Date: Jul. 24, 2003

(54) Semiconductor device having a die with a rhombic shape

(76) Inventors: Tai-Fa Young, Kaohsiung City (TW); Jiun-Feng Liou, Kaohsiung City (TW)

Correspondence Address: DICKINSON WRIGHT PLLC, Suite 800, 1901 L Street, N.W., Washington, DC, 20036, US

(21) Appl. No.: 10/052,467

(22) Filed: Jan. 23, 2002

(51) Int. Cl. H01L 31/0312; H01L 29/04; H01L 31/036

(52) U.S. Cl. 257/627; 257/77

(57) ABSTRACT

A semiconductor device has a semiconductor die with a rhombic shape and including a substrate with a hexagonal crystal structure, first and second semiconductor films formed on the substrate, and first and second metal contacts formed respectively on the semiconductor films. The hexagonal crystal structure has six equilateral sides. The semiconductor die has two parallel first side edges and two parallel second side edges, which extend in directions that are substantially parallel to respective ones of the six equilateral sides of the hexagonal crystal structure.

### BACKGROUND OF THE INVENTION

1. Field of the Invention

This invention relates to a semiconductor device having a die with a rhombic shape, and to a method for manufacturing the same.

2. Description of the Related Art

Semiconductor devices, such as light emitting diodes (LED), transistors, detectors, and the like, normally include a first semiconductor film and a second semiconductor film which are epitaxed on a substrate of sapphire or silicon carbide. The first semiconductor film is made of an n-type semiconductor material, whereas the second semiconductor film is made of a p-type semiconductor material so that the first and second semiconductor films define a p-n junction therebetween. When an electric current passes through the p-n junction, the LED emits light. Other LEDs may contain structures, such as p-i-n or multiple quantum wells, which are more efficient in light emitting than that of the p-n junction. It is known that the LED can emit blue light when the n- and p-type semiconductor materials are respectively n-doped and p-doped GaN (Gallium Nitride) semiconductor material.

The conventional LED is normally prepared by a process that includes processing steps of forming the first and second semiconductor films on the substrate by metal organic chemical vapor deposition (MOCVD) or by molecular beam epitaxy (MBE) techniques, forming exposed areas on the first semiconductor film via photo-masking and dry etching techniques, forming patterns of first metal contacts on the exposed areas of the first semiconductor film and second metal contacts on the second semiconductor film via lithographic and metallization techniques, rapid thermal annealing (RTA) of the assembly of the substrate, the first and second semiconductor films, and the first and second metal contacts, lapping the substrate of the assembly to facilitate subsequent processing, and dicing the assembly to form a plurality of semiconductor dies via a diamond cutting tool. Each semiconductor die is then subjected to wire bonding and chip packaging to form a semiconductor LEDpackage.

Conventionally, as illustrated in FIGS. 1A and 1B, wherein FIG. 1B is an enlarged view of an encircled portion of FIG. 1A, the aforesaid dicing step is performed by cutting the aforesaid assembly (indicated as reference number 1) along a plurality of longitudinal cutting lines 11 and a plurality of transverse cutting lines 12, which are orthogonal relative to each other, to form the semiconductor dies (indicated as reference number 10). As a consequence, the thus formed semiconductor dies 10 have a square cross-section. However, such way of dicing is only suitable for the substrate and/or the aforesaid semiconductor materials having a square cubic crystal structure. When the crystal structure of the substrate and/or the aforesaid semiconductor materials is not cubic but hexagonal or rhombic, the aforesaid longitudinal and transverse cutting lines 11, 12 will not be able to remain as straight as desired upon cutting (see FIG. 1B), thereby resulting in uneven side edges for the semiconductor dies 10. As a consequence, damage may occur on some of the semiconductor dies 10 due to the unevenness, thereby decreasing the production yield. Moreover, due to the discrepancy of the longitudinal and transverse cutting lines and the orientation of the crystal structure of the substrate and/or the aforesaid semiconductor materials, the substrate is required to be thinned to a relatively large extent so as to facilitate the subsequent dicing step, thereby resulting in weakening of the mechanical strength of the semiconductor dies 10. As a result, the semiconductor dies 10 will have a tendency to break during wire bonding.

### SUMMARY OF THE INVENTION

Therefore, the object of the present invention is to provide a semiconductor device that is capable of overcoming the aforementioned drawbacks.

Another object of the present invention is to provide a method for manufacturing the semiconductor device of this invention.

According to one aspect of the present invention, there is provided a semiconductor device comprising a semiconductor die having a rhombic shape and including a substrate that has a hexagonal crystal structure, a first semiconductor film formed on the substrate, a second semiconductor film formed on the first semiconductor film, a first metal contact formed on the first semiconductor film, and a second metal contact formed on the second semiconductor film. One of the first and second semiconductor films is made of an n-type semiconductor material. The other one of the first and second semiconductor films is made of a p-type semiconductor material. The hexagonal crystal structure has six equilateral sides. The semiconductor die has two parallel first side edges and two parallel second side edges, which extend in directions that are substantially parallel to respective ones of the six equilateral sides of the hexagonal crystal structure.

According to another aspect of the present invention, there is provided a method for manufacturing semiconductor devices. The method comprises the steps of: preparing a substrate having a hexagonal crystal structure with six equilateral sides; forming a first semiconductor film on the substrate; forming a second semiconductor film on the first semiconductor film, wherein one of the first and second semiconductor films is made of an n-type semiconductor material, and the other one of the first and second semiconductor films is made of a p-type semiconductor material; selectively masking and etching the second semiconductor film to define a plurality of orderly arranged exposed areas on the first semiconductor film which are exposed from the second semiconductor film; forming a plurality of orderly arranged first metal contacts on the exposed areas of the first semiconductor film, respectively, and a plurality of second metal contacts on the second semiconductor film, each of the second metal contacts being associated with a respective one of the first metal contacts; and dicing assembly of the substrate, the first semiconductor film, the second semiconductor film, the first metal contacts, and the second metal contacts along intersecting first and second cutting lines, which extend in directions that are substantially parallel to respective ones of the six equilateral sides of the hexagonal crystal structure, to form a plurality of semiconductor dies, each of which has a rhombic shape and each of which includes one of the first metal contacts and an associated one of the second metal contacts.

### BRIEF DESCRIPTION OF THE DRAWINGS

In drawings which illustrate an embodiment of the invention,

FIGS. 1A and 1B illustrate the formation of conventional semiconductor dies according to a conventional process for the production of semiconductor devices;

FIGS. 2A, 2B, 3, 4, 5, 6 illustrate consecutive steps for the formation of semiconductor dies according to a method embodying this invention; and

FIGS. 7A and 7B are top views of a semiconductor die formed according to the method of this invention.

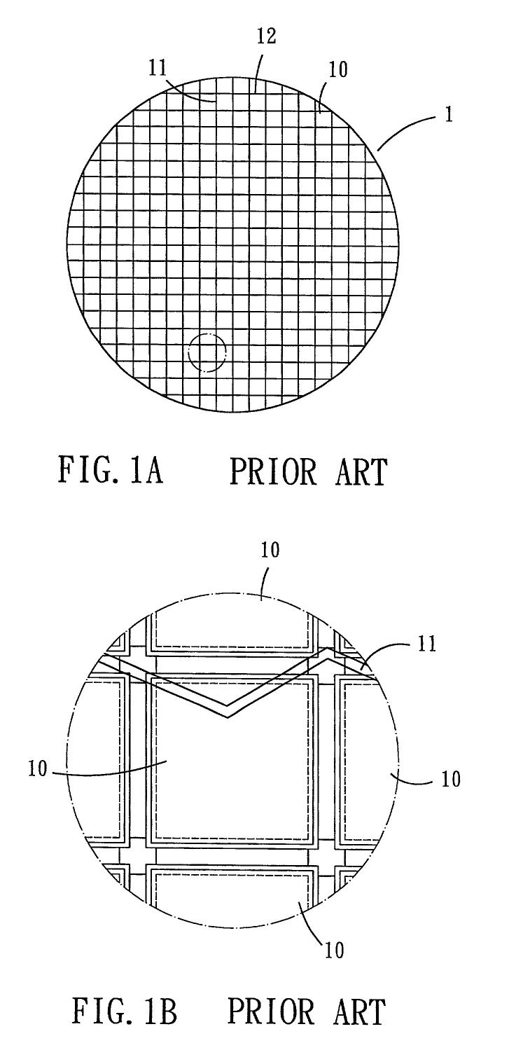

### DETAILED DESCRIPTION OF THE PREFERRED EMBODIMENT

This invention relates to a method for manufacturing semiconductor devices. The method comprises the steps of: preparing a substrate having a hexagonal crystal structure with six equilateral sides; forming a first semiconductor film on the substrate; forming a second semiconductor film on the first semiconductor film, wherein one of the first and second semiconductor films is made of an n-type semiconductor material, and the other one of the first and second semiconductor films is made of a p-type semiconductor material; selectively masking and etching the second semiconductor film to define a plurality of orderly arranged exposed areas on the first semiconductor film which are exposed from the second semiconductor film; forming a plurality of orderly arranged first metal contacts on the exposed areas of the first semiconductor film, respectively, and a plurality of second metal contacts on the second semiconductor film, each of the second metal contacts being associated with a respective one of the first metal contacts; and dicing assembly of the substrate, the first semiconductor film, the second semiconductor film, the first metal contacts, and the second metal contacts along intersecting first and second cutting lines, which extend in directions that are substantially parallel to respective ones of the six equilateral sides of the hexagonal crystal structure, to form a plurality of semiconductor dies, each of which has a rhombic shape and each of which includes one of the first metal contacts and an associated one of the second metal contacts.

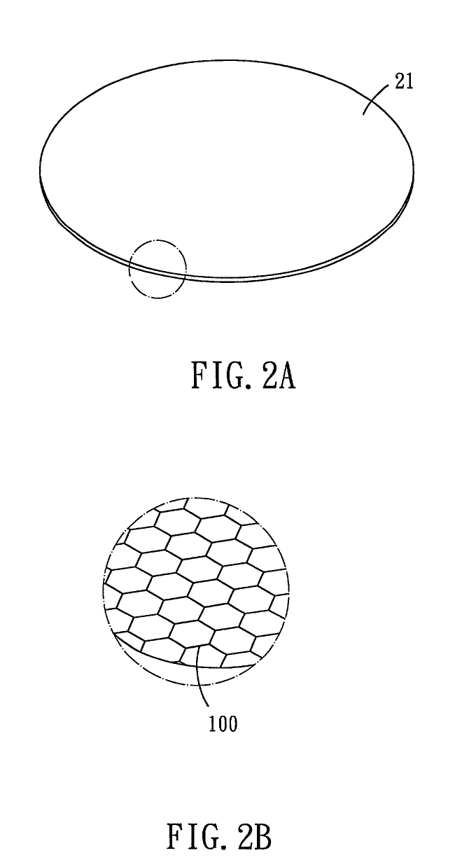

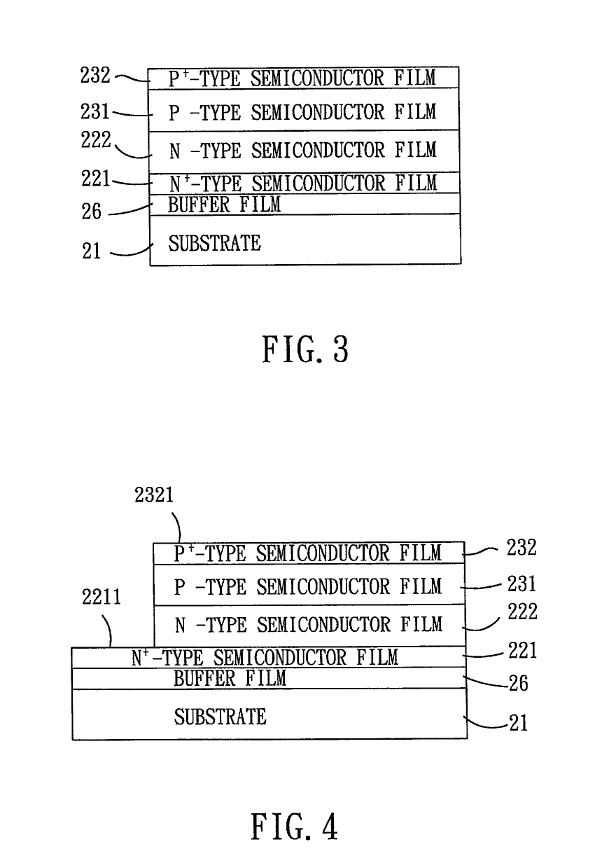

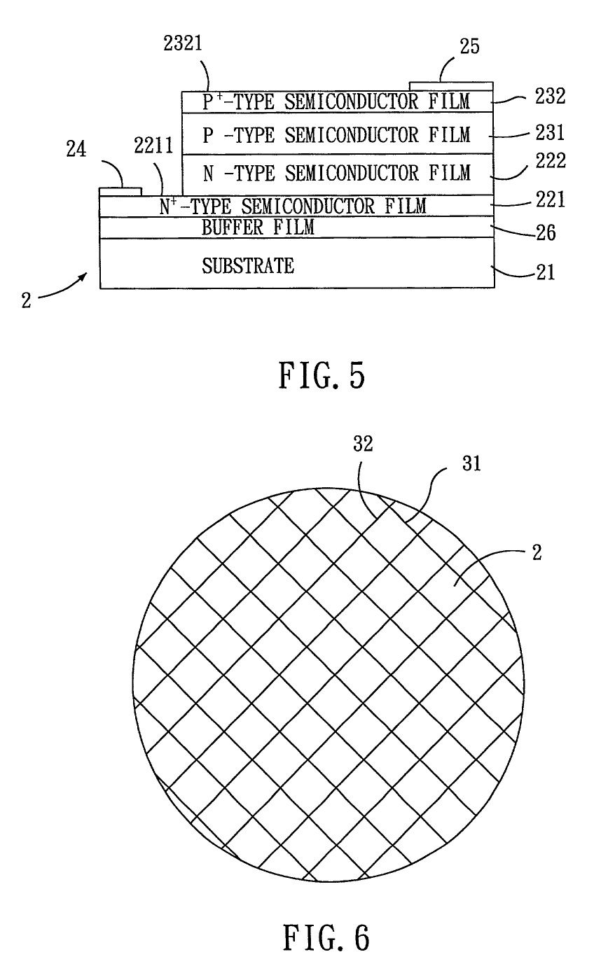

FIGS. 2A, 2B, 3, 4, 5, 6 illustrate the consecutive steps of a preferred embodiment of the method of this invention.

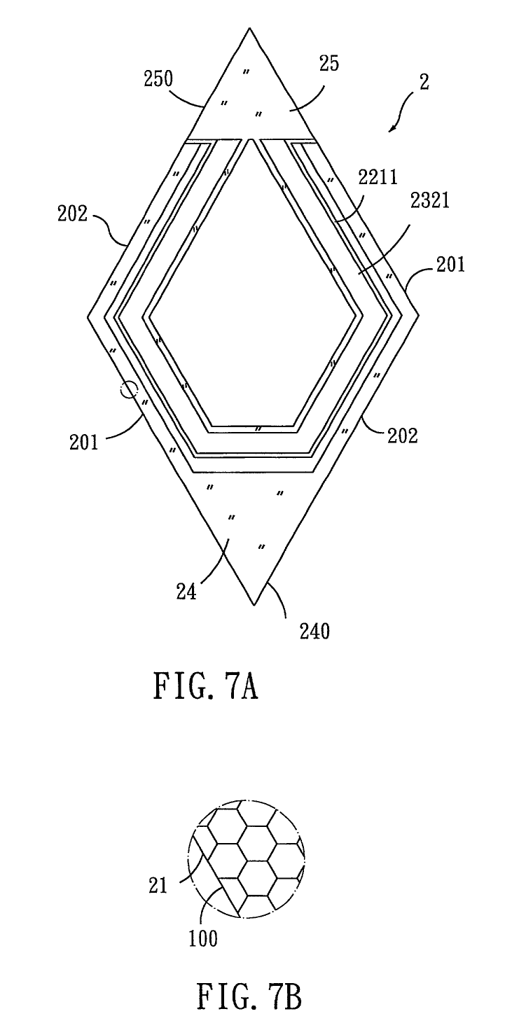

The processing steps in the preferred embodiment of the method of this invention includes: preparing a substrate 21 having a hexagonal crystal structure with six equilateral sides 100 (see FIG. 2B, which is an enlarged view of an encircled portion of FIG. 2A); forming a buffer film 26 on the substrate 21, forming a n⁺-type semiconductor film 221 on the buffer film 26; forming a n-type semiconductor film 222 on the n⁺-type semiconductor film 221; forming a p-type semiconductor film 231 on the n-type semiconductor film 22; forming a p⁺-type semiconductor film 232 on the p-type semiconductor film 231, the n⁺- and n-type semiconductor films 221, 222 and the p- and p⁺-type semiconductor films 231, 232 defining a p-n junction therebetween; selectively masking and etching the n-, p- and p⁺-type semiconductor films 222, 231, 232 to define a plurality of orderly arranged exposed areas 2211 on the n⁺-type semiconductor film 221 which are exposed from the n-, p- and p⁺-type semiconductor films 222, 231, 232; forming a plurality of orderly arranged n-electrode metal contacts 24 (only one contact is shown) on the exposed areas 2211 of the n⁺-type semiconductor film 221, respectively, and a plurality of p-electrode metal contacts 25 (only one contact is shown) on an upper surface 2321 of the p⁺-type semiconductor film 232, each of the p-electrode metal contacts 25 being associated with a respective one of the n-electrode metal contacts 24; and dicing assembly of the substrate 21, the n⁺- and n-type semiconductor films 221, 222, the p- and p⁺-type semiconductor films 231, 232, the n-electrode metal contacts 24, and the p-electrode metal contacts 25 along intersecting first and second cutting lines 31, 32, which extend in directions that are substantially parallel to respective ones of the six equilateral sides 100 of the hexagonal crystal structure, to form a plurality of semiconductor dies 2, each of which has a rhombic shape (see FIGS. 6 and 7A and 7B, wherein FIG. 7B is an enlarged view of an encircled portion of FIG. 7A) and each of which includes one of the n-electrode metal contacts 24 and an associated one of the p-electrode metal contacts 25. Each of the semiconductor dies 2 has two parallel first side edges 201 and two parallel second side edges 202, which extend in directions that are substantially parallel to respective ones of the six equilateral sides 100 of the hexagonal crystal structure (see FIG. 7B).

The thus formed semiconductor dies 2 are then subjected to wire bonding and packaging with epoxy resin to form semiconductor devices.

Preferably, the method of this invention can further include a step of forming metal contacting films (not shown) at locations where the n-electrode metal contacts 24 and the p-electrode metal contacts 25 are formed prior to the formation of the latter. These metal contacting films are to serve as ohmic contacts for increasing the interfacial contact between the n-electrode metal contacts 24 and the n⁺-type semiconductor film 221 and between the p-electrode metal contacts 25 and the p⁺-type semiconductor film 232.

Preferably, each of the n⁺- and n-type semiconductor films 221, 222 and the p- and p⁺-type semiconductor film 231, 232 has a hexagonal crystal structure that is the same as that of the substrate 21.

The substrate 21 is preferably made of a material selected from a group consisting of sapphire and silicon carbide. The n⁺- and n-type semiconductor films 221, 222 are preferably made of n-doped GaN (Gallium nitride) material, and the p- and p⁺-type semiconductor films 231, 232 are preferably made of p-doped GaN material. The n⁺-type semiconductor film 221 has a higher concentration of the dopant than that of the n-type semiconductor film 222. Similarly, the p⁺-type semiconductor film 232 has a higher concentration of the dopant than that of the p-type semiconductor film 231. The buffer film 26 is preferably made from aluminum nitride (AlN) or gallium nitride (GaN).

Referring now to FIG. 7A, each of the semiconductor dies 2 has two diagonal corners 240, 250, each of which forms an acute angle. The exposed area 2211 on the n⁺-type semiconductor film 221 of each semiconductor die 2 extends from one of the corners 240 along two adjacent ones of the side edges 201, 202 of the semiconductor die 2 to a location proximate to the other one of the corners 250. The n-electrode metal contact 24 of each semiconductor die 2 is formed on and extends along the exposed area 2211 of the n⁺-type semiconductor film 221. The p-electrode metal contact 25 of each semiconductor die 2 is formed on the upper surface 2321 of the p⁺-type semiconductor film 232 and extends from the other one of the corners 250 to a location proximate to said one of the corners 240.

The method of this invention can further include a step of thinning the substrate 21 of the assembly of the substrate 21, the n⁺- and n-type semiconductor films 221, 222, the p- and p⁺-type semiconductor films 231, 232, the n-electrode metal contacts 24, and the p-electrode metal contacts 25 prior to the dicing of the assembly so as to facilitate the dicing step.

The method of this invention can further include a step of forming grooves along the first and second cutting lines 31, 32 via photo-masking and etching techniques in order to facilitate the subsequent dicing step. In this step, a mask of metal film is selectively formed on the upper surface 2321 of the p⁺-type semiconductor film 232 and the exposed areas 2211 of the n⁺-type semiconductor film 221, while leaving the first and second cutting lines 31, 32 exposed therefrom. The n⁺- and n-type semiconductor films 221, 222 and the p- and p⁺-type semiconductor films 231, 232 at the first and second cutting lines 31, 32 are subsequently removed via etching techniques. The ratio of the extent of etching (fluorine is used as the etching agent) of the metal film employed in this step to the GaN material of the n⁺- and n-type semiconductor films 221, 222 and the p- and p⁺-type semiconductor films 231, 232 is about 1:10. The metal film can be a metal selected from a group consisting of platinum, gold, aluminum, and nickel.

Since the aforesaid first and second cutting lines 31, 32 extend in directions along the respective ones of the sides 100 of the hexagonal crystal structure, the degree of the thinning of the substrate can be significantly reduced and the drawbacks associated with the prior art as mentioned beforehand can be eliminated.

Moreover, by virtue of extending the n-electrode metal contact 24 from one of the corners 240 to the other one of the corners 250 of each semiconductor die 2, and the p-electrode metal contact 25 from the other one of the corners 250 to said one of the corners 240 of each semiconductor die 2, the electric current, which passes through the p-n junction of the semiconductor die 2, can be distributed uniformly across the p-n junction, thereby increasing the light-emitting efficiency of the semiconductor device of this invention.

With the invention thus explained, it is apparent that various modifications and variations can be made without departing from the spirit of the present invention. It is therefore intended that the invention be limited only as recited in the appended claims.

We claim:

1. A semiconductor device comprising:
a semiconductor die having a rhombic shape and including a substrate that has a hexagonal crystal structure, a first semiconductor film formed on said substrate, a second semiconductor film formed on said first semiconductor film, a first metal contact formed on said first semiconductor film, and a second metal contact formed on said second semiconductor film, one of said first and second semiconductor films being made of an n-type semiconductor material, the other one of said first and second semiconductor films being made of a p-type semiconductor material, said hexagonal crystal structure having six equilateral sides, said semiconductor die having two parallel first side edges and two parallel second side edges, which extend in directions that are substantially parallel to respective ones of said six equilateral sides of said hexagonal crystal structure.

2. The semiconductor device of claim 1, wherein each of said first and second semiconductor films has a hexagonal crystal structure that is the same as that of said substrate.

3. The semiconductor device of claim 1, wherein said substrate is made of a material selected from a group consisting of sapphire and silicon carbide.

4. The semiconductor device of claim 2, wherein said n-type semiconductor material is n-doped GaN material, and said p-type semiconductor material is p-doped GaN material.

5. The semiconductor device of claim 1, wherein said semiconductor die further includes a buffer film which is selected from a group consisting of aluminum nitride and gallium nitride, and which is sandwiched between said substrate and said first semiconductor film.

6. The semiconductor device of claim 1, wherein said semiconductor die has two diagonal corners, each of which forms an acute angle, said first semiconductor film having an exposed area that is exposed from said second semiconductor film and that extends from one of said corners along at least one of said side edges of said semiconductor die to a location proximate to the other one of said corners, said first metal contact being formed on and extending along said exposed area of said first semiconductor film, said second semiconductor film having an upper surface, said second metal contact being formed on said upper surface and extending from the other one of said corners to a location proximate to said one of said corners.

7. A method for manufacturing semiconductor devices, comprising the steps of:
preparing a substrate having a hexagonal crystal structure with six equilateral sides;
forming a first semiconductor film on said substrate;
forming a second semiconductor film on said first semiconductor film, wherein one of said first and second semiconductor films is made of an n-type semiconductor material, and the other one of said first and second semiconductor films is made of a p-type semiconductor material;
selectively masking and etching said second semiconductor film to define a plurality of orderly arranged exposed areas on said first semiconductor film which are exposed from said second semiconductor film;
forming a plurality of orderly arranged first metal contacts on said exposed areas of said first semiconductor film, respectively, and a plurality of second metal contacts on said second semiconductor film, each of said second metal contacts being associated with a respective one of said first metal contacts; and
dicing assembly of said substrate, said first semiconductor film, said second semiconductor film, said first metal contacts, and said second metal contacts along intersecting first and second cutting lines, which extend in directions that are substantially parallel to respective ones of said six equilateral sides of said hexagonal crystal structure, to form a plurality of semiconductor dies, each of which has a rhombic shape and each of which includes one of said first metal contacts and an associated one of said second metal contacts.

8. The method of claim 7, further comprising a step of forming a buffer film on said substrate prior to the formation of said first semiconductor film.

9. The method of claim 7, further comprising a step of thinning said substrate prior to dicing of said assembly of said substrate, said first semiconductor film, said second semiconductor film, said first metal contacts, and said second metal contacts.

10. The method of claim 7, wherein each of said first and second semiconductor films has a hexagonal crystal structure that is the same as that of said substrate.

11. The method of claim 7, wherein said substrate is made of a material selected from a group consisting of sapphire and silicon carbide.

12. The method of claim 7, wherein said n-type semiconductor material is n-doped GaN material, and said p-type semiconductor material is p-doped GaN material.
